(19) United States
(12) Patent Application Publication
(10) Pub. No.: US 2025/0111113 A1
(43) Pub. Date: Apr. 3, 2025

(54) GENERATING SYNTHESIZABLE REGISTER TRANSFER LEVEL DESIGNS

(71) Applicant: Intel Corporation, Santa Clara, CA (US)

(72) Inventors: Rakesh KANDULA, Bangalore (IN); Ravishankar D, Mysore (IN)

(21) Appl. No.: 18/375,349

(22) Filed: Sep. 29, 2023

(51) Int. Cl. G06F 30/327

(52) U.S. Cl. CPC G06F 30/327

(57) ABSTRACT

Methods that are useful in semiconductor chip design are presented. A microarchitectural structured flow chart can be processed and converted into register transfer level hardware description language code. Processing of the flow chart can include detecting shapes, lines, colors, and text. The shapes that are detected can be rounded, rhombus, and rectangle and a rounded shape can represent a state, a rhombus can represent a decision, and a rectangle can represent an assignment for a finite state machine.

### FIELD

Descriptions are generally related to semiconductor chip manufacturing, and more particular descriptions are related to semiconductor chip hardware design for semiconductor chip manufacturing.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller, the number of features grows, and performance demands increase. Challenges include, for example, decreased time to market, complexity, precision and scaling requirements, power delivery requirements, limited failure tolerance, and material and manufacturing costs.

Semiconductor chip design has numerous stages. Circuit and hardware layout usually begins with an architectural specification. The architectural specifications are drafted at levels of abstraction above the final physical design. Verilog and system Verilog are hardware description languages (HDLs) that describe electronic systems in a format that allows development, verification, synthesis, and testing of the hardware design. Verilog is standardized as Institute of Electrical and Electronics Engineers (IEEE) 1364 and system Verilog is standardized at IEEE 1800. The Verilog or system Verilog description can allow verification of an architectural design through simulation, timing and test analysis, and/or logic synthesis. Register transfer level (RTL) descriptions are used to enumerate logical operations and transfers between registers of a processor using Verilog or system Verilog hardware description languages. Developing RTL descriptions can be time-consuming because it can involve complex control logic having multiple conditions, many sequences of events, and numerous corner cases.

### BRIEF DESCRIPTION OF THE DRAWINGS

The figures are provided to aid in understanding the invention. The figures can include diagrams and illustrations of exemplary structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the invention.

FIG. 1 illustrates an exemplary process used for semiconductor chip design.

FIG. 2 provides an additional exemplary process for semiconductor chip design.

FIG. 3 illustrates a method for converting a structured flow chart that describes one or more aspects of a computer architecture or microarchitecture to a data description of the information contained in the structured flow chart.

FIG. 4 shows an exemplary structured flow chart.

FIG. 5 illustrates aspects of a method for detecting shapes in an image.

FIG. 6 shows a flow chart recreation of the exemplary structured flow chart of FIG. 4.

FIGS. 7A-7B provide an exemplary mapping of a structured flow chart to hardware descriptive language code.

FIG. 8 provides an exemplary computing system that can be used to perform methods described herein.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation of the invention. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following after some other event or events. Other sequences of operations can also be performed according to alternative embodiments. Furthermore, additional operations may be added or removed depending on the particular application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Terms such as chip, die, IC (integrated circuit) chip, IC die, microelectronic chip, microelectronic die, or semiconductor chip are used interchangeably and refer to a semiconductor device comprising integrated circuits.

Flow diagrams as illustrated herein provide examples of sequences of various process actions. The flow diagrams can indicate operations to be executed by a software or firmware routine, as well as physical operations. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted and not all implementations will perform all actions.

Various components described can be a means for performing the operations or functions described. Each component described includes software, hardware, or a combination of these. The components can be implemented as software modules, hardware modules, special-purpose hardware (for example, application specific hardware, application specific integrated circuits (ASICs), digital signal processors (DSPs), etc.), embedded controllers, or hardwired circuitry).

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium comprising non-transitory instructions can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). A communication interface includes any mechanism that interfaces to, for example, a hardwired, wireless, or optical medium to communicate to another device, such as, for example, a memory bus interface, a processor bus interface, an Internet connection, a disk controller.

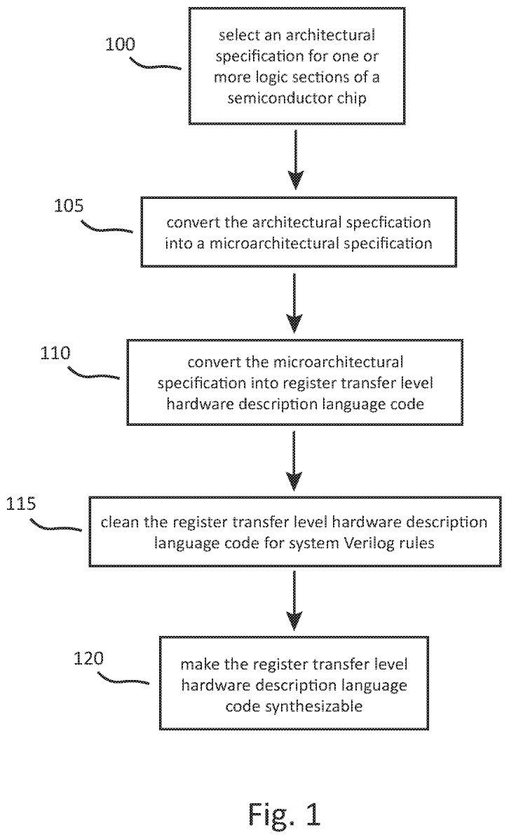

FIG. 1 illustrates an exemplary method useful for semiconductor chip design. In FIG. 1, an architectural specification for a semiconductor chip to be manufactured is developed 100. The architectural specification is converted into a microarchitectural specification 105. The architectural and microarchitectural specifications can be abstractions that describe desired circuit behavior. The architectural and microarchitectural specifications are converted into register transfer level hardware description language code 110. The RTL HDL code can be written in a hardware description language, such as, for example, Verilog or system Verilog. Other useful HDLs include, for example, VHSIC (very high speed integrated circuits) HDL (VHDL) (IEEE Standard 1076). Creating RTL HDL code can be a complex process because there can be, for example, complex control logic, having many conditions and multiple sequences of events, that needs to be implemented though dense finite state machines (FSMs). A dense FSM can have more than 50 states. In some examples, a dense FSM can have 200 to 300 states. Aligning FSM implementations to the architectural and microarchitectural specifications is an important part of generating RTL HDL code.

The RTL HDL code is cleaned for system Verilog (or other HDL code) rules such as, for example, through linting processes 115. Linting provides automated code checking for, for example, programming errors, compatibility to the RTL compilers, and/or correct use of standard syntaxes for lint tools such as, for example, spyglass. The RTL HDL code is made synthesizable 120. Synthesis of RTL HDL code is a process in which the RTL HDL code is converted into a logic gate-level design implementation for a semiconductor chip architecture. The design implementation can be a connection table that includes gates and functional blocks of logic and it can also include functional and timing behavior. At this stage, the RTL HDL code is cleaned to remove, for example, combinational loops, unintended laches, unintended default statements, unreachable assign statements, and/or conditions. Synthesizable RTL hardware description language code means that the RTL HDL code does not have mismatches between the silicon chip behavior and the simulation behavior. Examples of RTL HDL codes that have silicon-simulation mismatches include, for example, timing loops, unintended latches, and unreachable RTL HDL code statements. Synthesis of RTL HDL code can involve mapping functionality to libraries of standard circuits, such as, for example, NOT, AND, OR, NAND, NOR, XOR, laches, flip-flops, registers, ring counters, and/or other more complex operations such as, for example, logic operations, arithmetic operations, and/or control flow operations.

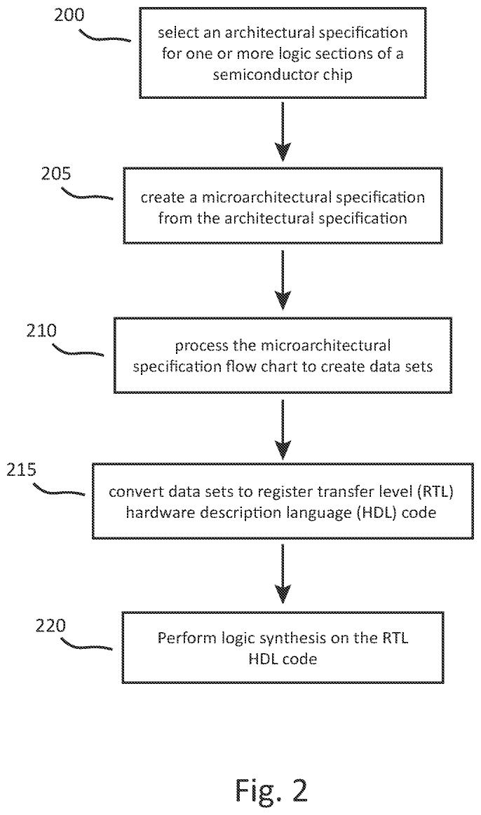

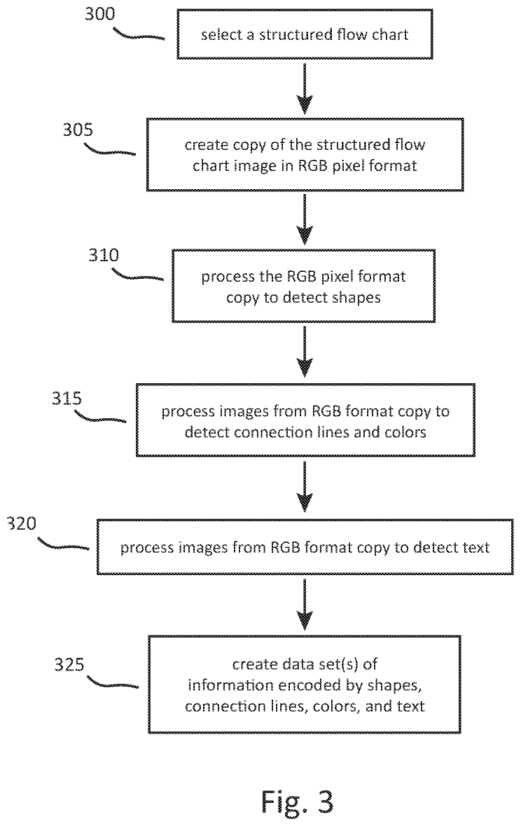

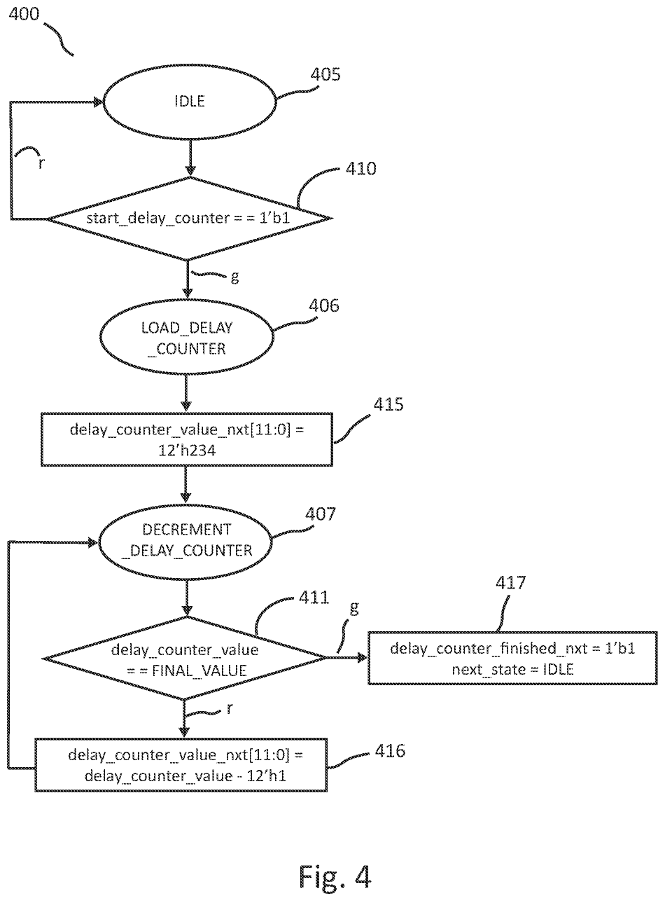

FIG. 2 depicts an alternate process useful for semiconductor chip design. The method of FIG. 2 can be implemented in programming language, such as, C, C++, Java, or Python. The process of FIG. 2, an architectural specification for one or more logic sections of a semiconductor chip is selected 200. A semiconductor chip can be broken into sections called logic (or logical) partitions and each logic partition can have separate architectural specifications. A microarchitectural specification is created from the architectural specification 205. The microarchitectural specification can be in the form of a structured flow chart that describes operations and functions for one or more logic partitions of the chip, such as, for example, logic operations, arithmetic operations, and/or control flows. The microarchitectural specification flow chart can be in a program format such as, for example, Visio, Microsoft document, Microsoft paint, Diagrams Notepad, Adobe Illustrator, or other program that allows creation of visual flow charts. The images in the microarchitectural flow chart are processed to create data sets 210. Exemplary data sets are shown and described herein, for example FIGS. 4-6 illustrate an exemplary method for converting structured flow charts to data descriptions in the form of data sets. The data description of the microarchitectural specification flow chart is converted to RTL HDL code 215 that is in the form of a hardware description language, such as Verilog or system Verilog, code. Other HDLs that can be used include, for example, VHSIC (very high speed integrated circuits) HDL (VHDL). The RTL HDL code that is created can be Lint clean (meaning that errors that Linting would be used to fix are not present in the code) and synthesizable (meaning that errors that would be cleaned from the RTL HDL code before synthesis in the method of FIG. 1 are not present in the RTL HDL code). These design implementations can also be higher-level representations of circuits, however they can be used to create lower-level representations and actual physical circuit-level devices. In the method of FIG. 3, the process of checking the RTL HDL code through linting processes does not have to be performed. Additionally, the RTL HDL code does not have to be cleaned to remove, for example, combinational loops, unintended laches, unintended default statements, unreachable assign statements, and/or conditions, such as is done in the method of FIG. 2. Logic synthesis is performed to convert RTL hardware description language code into, for example, a netlist containing registers and Boolean equations 220.

FIG. 3 illustrates an exemplary method for taking a structured flow chart and converting it to a data description of the information in the flow chart. The method of FIG. 3 is useful, for example, as part of the method described in FIG. 2 in which a semiconductor chip design can be processed. In FIG. 3, a structured flow chart is selected 300. The structured flow chart can be an architectural or a microarchitectural description of one or more sections of a semiconductor chip. The structured flow chart is copied to as an image to RGB (red green blue) pixel format 305. RGB format is a system for representing colors in a digital image or display. The structured flow chart can be copied as an image to RGB format by, for example, using the Python Pillow (or other programming language module) with OpenCV. Shapes are detected from the RBG pixel file 310. Connecting lines and line colors are detected from the RBG format file 315. Text is detected from the RBG pixel file 320. Detection can be accomplished using, for example, programming languages such as C, C++, Java, Python, and/or Microsoft Visual Studio to process images in the file. Other languages are also possible and methods herein are not limited to a particular programming language. Shapes in the RGB format file can be detected, for example, using Python Pillow and OpenCV for image processing. In the example conversion of FIGS. 4-6 and 7A-7B, Python has been used to further illustrate methods for converting a structured flow chart, that represents information in both a visual and a text format, to a data description of the visual and text information in the chart. Information associating text with shapes, shapes with lines, and lines with colors, for example, is preserved during the conversion process by creating data sets 325. The data sets can be in the form of ordered arrays where data is ordered in an array by its location in the RGB pixel format image.

FIG. 4 provides an example of a structured flow chart 400. In FIG. 4, complex control logic is represented by rounded blocks 405, 406, and 407 indicating “STATE,” by rhombus blocks 410 and 411 for “DECISION,” and by rectangle blocks 415, 416, and 417 for “ASSIGNMENT.” (The rounded blocks 405, 406, and 407 can be shapes, such as circles or ovals.) The “STATE,” “DECISION,” and “ASSIGNMENT” can be that of a finite state machine (FSM) and complex FSMs can be represented in this way. These representations of FSMs can be scalable to generate much more complex FSMs having greater than 50 states or even greater than 200 states, such as for example, 200-300 states. Complex control logic that has multiple conditions and sequences of events can be implemented using finite state machines. Lines that are red (if no) or green (if yes) are indicated in FIG. 4 by an “r” or a “g,” respectively. The structured flow chart of FIG. 4 is provided as an example, other types of structured flow charts can also be used in the methods described herein.

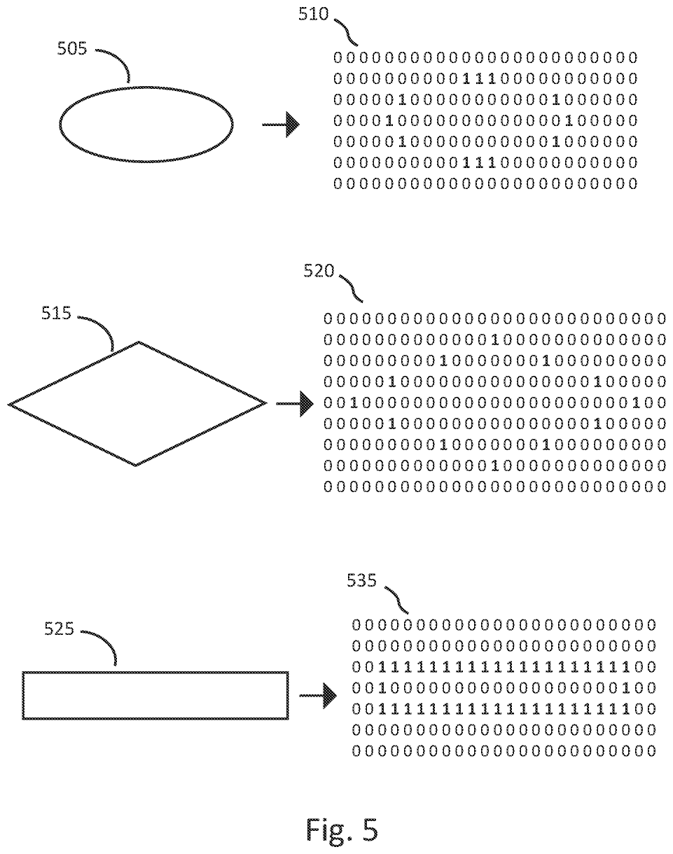

FIG. 5 illustrates a method for detecting shapes in a structured flow chart. The structured flow chart can be the chart illustrated in FIG. 4, however other structured flow charts are possible. The structured flow chart can be, for example, a Visio, Microsoft document, Microsoft paint, Diagrams Notepad, Adobe Illustrator image format. The structured flow chart is converted to RBG pixel format using for example, the Python Pillow package. Shapes of objects can be detected using the OpenCV package in Python. (Other programming languages are also possible.) The Python OpenCV package screens the flow chart in a white background and whenever a line or a non-empty space is found, it puts a “1” in a matrix and whenever no line is found it puts a “0” in the matrix. A non-empty space is perceived as pixel RGB (0,0,0) which is a non-empty space with a black color. In FIG. 5, an oval 505 has been converted into a matrix 510, a rhombus 515 has been converted into a matrix 520, and a rectangle 525 has been converted into a matrix 535. If the structured flow chart is the one shown in FIG. 4, the following array can be created from detected shapes:
process1(ASSIGNMENT/RECTANGLE),
process2(ASSIGNMENT/RECTANGLE),
decision3(DECISION/RHOMBUS),
startend4(STATE/CIRCLE),
process5(ASSIGNMENT/RECTANGLE),
startend6(STATE/CIRCLE),
decision7(DECISION/RHOMBUS),
startend8(STATE/CIRCLE)

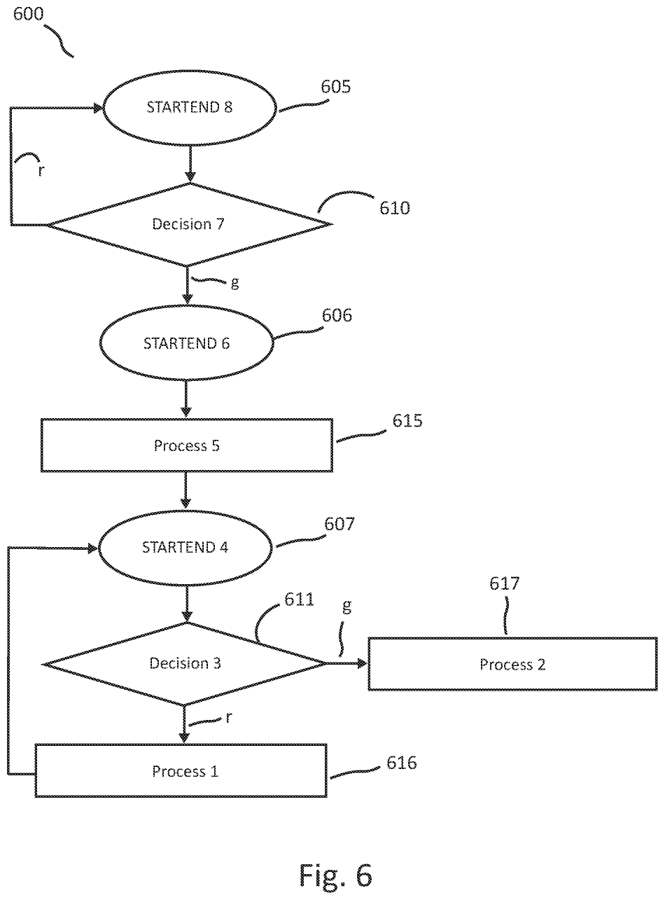

FIG. 6 provides a partial recreation of the structured flow chart of FIG. 4 (600) as part of the process of converting the visual and text-based information in a structured flow chart into a data description. Data descriptions are in the form of ordered arrays. Lines that are red or green are indicated in FIG. 6 by an “r” or a “g,” respectively. The structured flow chart partial recreation 600 has circles (ovals) 605, 606, and 607, rhombuses 610 and 611, and rectangles 615, 616, and 617. An exemplary line detection algorithm begins at the bottom of a structured flow chart recreation 600 and creates two ordered arrays:
OBJECTS CONNECTION:
Start connection
[‘process1’, ‘decision3’, ‘decision3’, ‘startend4’, ‘process5’, ‘startend6’, ‘decision7’, ‘decision7’, ‘startend8’]
Stop connection
[‘startend4’, ‘process2’, ‘process1’, ‘decision3’, ‘startend4’, ‘process5’, ‘startend6’, ‘startend8’, ‘decision7’]
   The first ordered array is the start of the line connection and the second ordered array is the end of the line connection. It is also possible to start at the top of structured flow chart recreation 600. An ordered decision array is created from the structured flow chart recreation 600:
OBJECTS CONNECTION PROPERTIES:
[‘na’, ‘yes’, ‘no’, ‘na’, ‘na’, ‘na’, ‘yes’, ‘no’, ‘na’]
   In the “Objects Connection Properties” array or decision array, ‘na’ indicates a line that is not starting from a decision, ‘yes’ indicates a line that is starting from a decision and the condition is true (green line), and ‘no’ indicates that the line is starting from a decision and the condition is false (red line). Connections between objects and line colors (red, green, and black, in this example) are detected. The ordered decision array can be used to create “if-else” system Verilog code statements. In this example, a line going from a decision box (rhombus) as yes (green)/no(red) to assignment (rectangle) or to state (circle) can be detected. Additionally, a line going from decision box (rhombus) to state (circle) or to assignment (rectangle) can be detected. A line going from state (circle) to assignment (rectangle) or to decision box (rhombus) can also be detected.

If not already available in a useful format, text from the exemplary structured flow chart of FIG. 4 can be provided to a text reader to extract written data. The text reader can be, for example, Tesseract Optical Character Recognition (OCR). Starting at the bottom of the structured flow chart of FIG. 4 (it is also possible to start at the top), the text array that is created can be, for example:
delay_counter_value_nxt[11:0]=delay_counter_value−12′h1,
delay_counter_finished_nxt=1′b1
next_state=IDLE,
delay_counter_value==FINAL_VALUE, DECREMENT_DELAY_COUNTER,
delay_counter_value_nxt[11:0]=12′h234,
LOAD_DELAY_COUNTER,
start_delay_counter==1′b1,
IDLE

The exemplary data sets of the structured flow chart of FIG. 4 as described herein and in FIGS. 5-6, can be used to generate system Verilog RTL HDL code or other code useful in the semiconductor chip design process (such as, for example, VHDL, Verilog, or any other hardware descriptive language). Data sets in the form of ordered arrays that are generated as a result of detecting shapes, lines, colors, interconnections between objects, and text, are used to convert the information contained in a structured flow chart into a RTL hardware description language code format. Data arrays are ordered arrays in which data is ordered by its location in the structured flow chart. The following exemplary explanation uses system Verilog as the hardware description language for a RTL conversion module, however, other HDL formats can also be generated using the methods described herein, such as for example, VHDL or Verilog. The following algorithm (Algorithm A) can be used by a RTL conversion module to convert the data in the arrays from the structured flow chart to computer code, such as code comprising system Verilog RTL HDL code statements.

### Algorithm A:

1) for a decision block (rhombus), text having variables on the left side of an equation is considered as an input port, and text on the right side of an equation is considered as an output port;
2) for a process (rectangle), text having variables on the right side of an equation is considered as an input port, and text on the left side of an equation is considered as an output port; and
3) if a variable is found in both an input and an output table, then the variable is deleted from the input and the output tables and added as logic in the form of a logic variable.
   The RTL conversion module includes creating at least one table of input ports and at least one table of output ports. In part (3) of Algorithm A, the logic can be in the form of a register or a wire, for example, if the HDL is in Verilog format. The RTL conversion module that generates system Verilog code extracts FSM states from flowchart. The first state is considered as default. All variables with *_nxt are assigned to their own variable without _nxt. In the script all *_nxt are considered as internal variables (logic) and will not be considered as input/output ports. The variables without _nxt, are considered as input/output ports based on Algorithm A (3). In Verilog, ports are a set of signals that act as inputs and outputs for a module and are how a module is communicated with. A module is a block of Verilog code that implements a function. A wire creates physical connections between devices and allows electrical communication between devices. A register is a memory element (circuit device) that can store values.

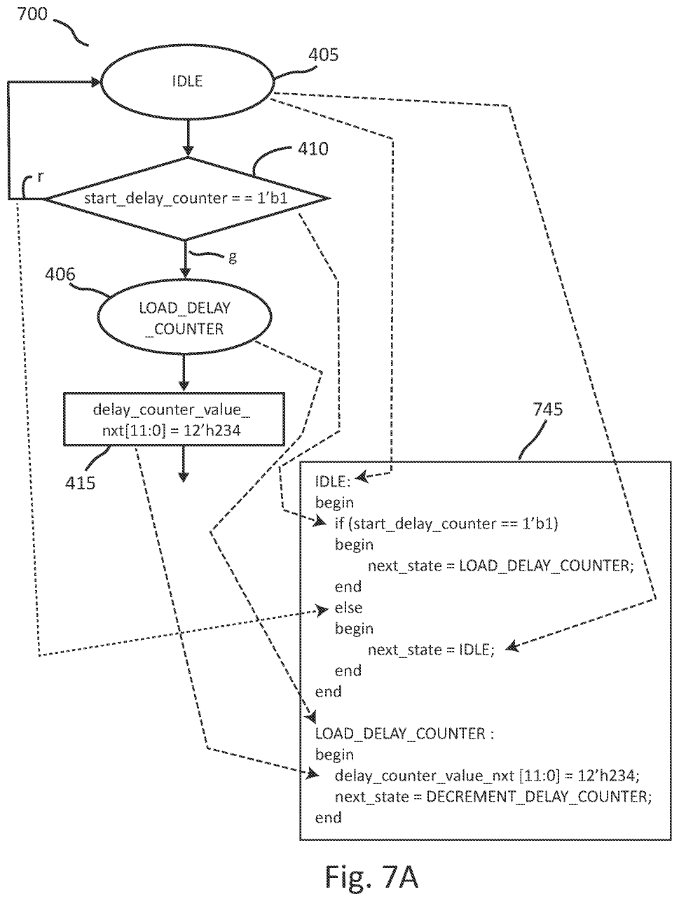

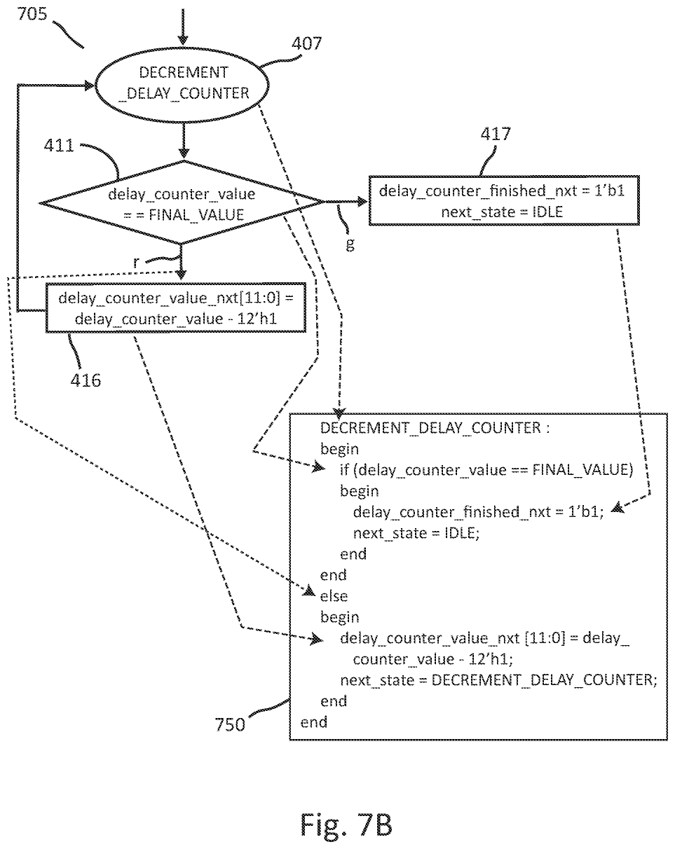

FIGS. 7A-7B illustrate an exemplary mapping of a structured flow chart to hardware descriptive code. In FIG. 7A, a section of the exemplary structured flow chart of FIG. 4 (700) has been provided. Structured flow chart section 700 contains complex control logic that is represented by rounded blocks 405 and 406, indicating “STATE,” by rhombus block 410 for “DECISION,” and by rectangle block 415 for “ASSIGNMENT.” FIG. 7B provides a further section of the exemplary structured flow chart of FIG. 4 (705). In structured flow chart section 705, complex control logic is represented by rounded block 407 indicating “STATE,” by rhombus block 411 for “DECISION,” and by rectangle blocks 416 and 417 for “ASSIGNMENT.” The mapping of the control logic to the system Verilog code according to Algorithm A (above), is shown in box 745 (FIG. 7A) and box 750 (FIG. 7B) and by dashed arrows between the state, decision, and assignment blocks and the resulting system Verilog code section in box 745 or box 750.

The RTL conversion module that generates RTL hardware description language code can also add comment lines that contain text descriptions. The generated code can also contain statements such as “input logic clk” and “input logic rst.” These statements are generated during structured flowchart conversion. A RTL system Verilog code must have clk (clock) and rst (reset) ports. Additionally, the system Verilog RTL HDL code that is generated by the RTL conversion module can be indented for readability. For example, whenever a “begin” is found, a two space indentation is performed. Whenever an “end” is found, the indentation of the line is reduced by two spaces.

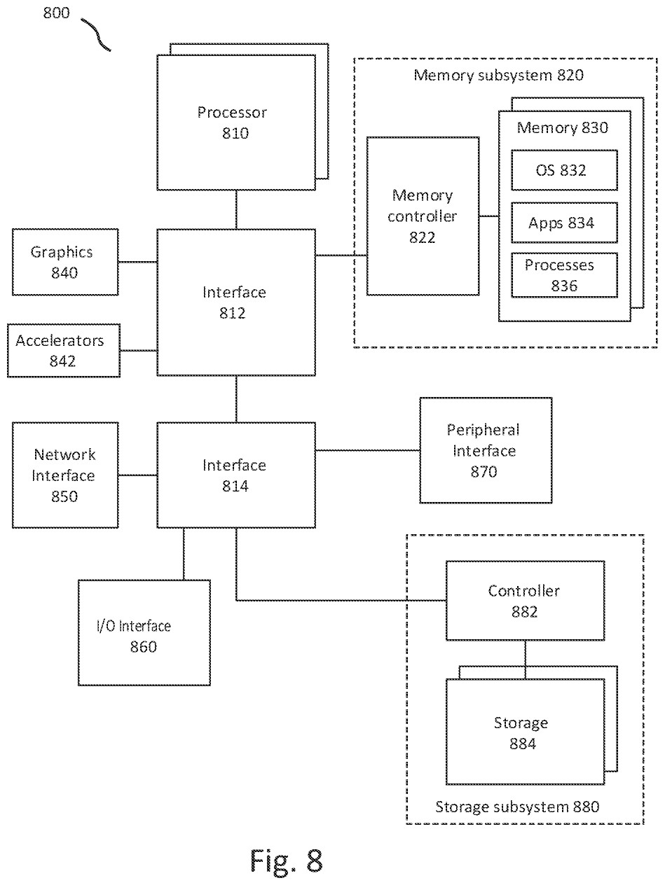

FIG. 8 depicts an example computing system which can be used to perform the methods described herein. For example, instructions for performing one or more aspects of the processes described in FIGS. 4-6, and 7A-7B can be stored and/or run on the computing system. The computing system employed can include more, different, or fewer features than the one described with respect to FIG. 8.

Computing system 800 includes processor 810, which provides processing, operation management, and execution of instructions for system 800. Processor 810 can include any type of microprocessor, CPU (central processing unit), GPU (graphics processing unit), processing core, or other processing hardware to provide processing for system 800, or a combination of processors or processing cores. Processor 810 controls the overall operation of system 800, and can be or include, one or more programmable general-purpose or special-purpose microprocessors, DSPs, programmable controllers, ASICs, programmable logic devices (PLDs), or the like, or a combination of such devices.

In one example, system 800 includes interface 812 coupled to processor 810, which can represent a higher speed interface or a high throughput interface for system components needing higher bandwidth connections, such as memory subsystem 820 or graphics interface components 840, and/or accelerators 842. Interface 812 represents an interface circuit, which can be a standalone component or integrated onto a processor die. Where present, graphics interface 840 interfaces to graphics components for providing a visual display to a user of system 800. In one example, the display can include a touchscreen display.

Accelerators 842 can be a fixed function or programmable offload engine that can be accessed or used by a processor 810. For example, an accelerator among accelerators 842 can provide data compression (DC) capability, cryptography services such as public key encryption (PKE), cipher, hash/authentication capabilities, decryption, or other capabilities or services. In some cases, accelerators 842 can be integrated into a CPU socket (e.g., a connector to a motherboard (or circuit board, printed circuit board, mainboard, system board, or logic board) that includes a CPU and provides an electrical interface with the CPU). For example, accelerators 842 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 842 can provide multiple neural networks, CPUs, processor cores, general purpose graphics processing units, or graphics processing units can be made available for use by artificial intelligence (AI) or machine learning (ML) models.

Memory subsystem 820 represents the main memory of system 800 and provides storage for code to be executed by processor 810, or data values to be used in executing a routine. Memory subsystem 820 can include one or more memory devices 830 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 830 stores and hosts, among other things, operating system (OS) 832 that provides a software platform for execution of instructions in system 800, and stores and hosts applications 834 and processes 836. In one example, memory subsystem 820 includes memory controller 822, which is a memory controller to generate and issue commands to memory 830. The memory controller 822 could be a physical part of processor 810 or a physical part of interface 812. For example, memory controller 822 can be an integrated memory controller, integrated onto a circuit within processor 810.

System 800 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 800 includes interface 814, which can be coupled to interface 812. In one example, interface 814 represents an interface circuit, which can include standalone components and integrated circuitry. In one example, user interface components or peripheral components, or both, couple to interface 814. Network interface 850 provides system 800 the ability to communicate with remote devices (e.g., servers or other computing devices) over one or more networks. Network interface 850 can include an Ethernet adapter, wireless interconnection components, cellular network interconnection components, USB, or other wired or wireless standards-based or proprietary interfaces. Network interface 850 can transmit data to a device that is in the same data center or rack or a remote device, which can include sending data stored in memory.

Some examples of network interface 850 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that could have been performed by a CPU. The IPU or DPU can include one or more memory devices.

In one example, system 800 includes one or more input/output (I/O) interface(s) 860. I/O interface 860 can include one or more interface components through which a user interacts with system 800 (e.g., audio, alphanumeric, tactile/touch, or other interfacing). Peripheral interface 870 can include additional types of hardware interfaces, such as, for example, interfaces to semiconductor fabrication equipment and/or electrostatic charge management devices.

In one example, system 800 includes storage subsystem 880. Storage subsystem 880 includes storage device(s) 884, which can be or include any conventional medium for storing data in a nonvolatile manner, such as one or more magnetic, solid state, and/or optical based disks. Storage 884 can be generically considered to be a “memory,” although memory 830 is typically the executing or operating memory to provide instructions to processor 810. Whereas storage 884 is nonvolatile, memory 830 can include volatile memory (e.g., the value or state of the data is indeterminate if power is interrupted to system 800). In one example, storage subsystem 880 includes controller 882 to interface with storage 884. In one example controller 882 is a physical part of interface 812 or processor 810 or can include circuits or logic in both processor 810 and interface 814.

A power source (not depicted) provides power to the components of system 800. More specifically, power source typically interfaces to one or multiple power supplies in system 800 to provide power to the components of system 800.

Exemplary systems may be implemented in various types of computing, smart phones, tablets, personal computers, and networking equipment, such as switches, routers, racks, and blade servers such as those employed in a data center and/or server farm environment.

Exemplary methods for converting a flow chart are provided. Exemplary methods comprise selecting a microarchitectural specification for at least a portion of a semiconductor chip wherein the microarchitectural specification is in a form of a structured flow chart, detecting shapes in the structured flow chart and generating a first array of values wherein the first array of values comprises a value for each shape detected and the values of the first array of values are ordered according to locations of the shapes detected, detecting lines in the structured flow chart and generating a second array of values wherein the second array of values comprises a value for each line detected and the values of the second array of values are ordered according to locations of the lines detected, detecting text in the structured flow chart and generating a third array of values wherein the third array of values comprises a value for each block of text detected and values of the third array are ordered by location of the text detected, and converting information contained in the first array of values, the second array of values, and the third array of values into a register transfer level hardware description language code. A hardware description language is, for example, system Verilog, very high speed integrated circuits hardware description language, or Verilog. Exemplary methods can also include creating a copy of the structured flow chart wherein the copy is in red green blue (RGB) pixel format. In further exemplary methods, the shapes detected are rounded, rhombus, and rectangle. A rounded shape can represent state, a rhombus can represent a decision, and a rectangle can represent an assignment for a finite state machine. In additional exemplary methods, if a portion of the text that is detected is associated with a detected shape, wherein the detected shape is a rhombus, wherein the portion of the text that is detected comprises an equation and variables, then the variables on a left side of the equation are considered as an input port. In further exemplary methods, if a portion of the text that is detected is associated with a detected shape, wherein the detected shape is a rhombus, wherein the portion of the text that is detected comprises an equation and variables, then the variables on a right side of the equation are considered as an output port. In additional exemplary methods, if a portion of the text that is detected is associated with a detected shape, wherein the detected shape is a rectangle, wherein the portion of the text that is detected comprises an equation and variables, then the variables on a right side of the equation are considered as an input port. In additional exemplary methods, if a portion of the text that is detected is associated with a detected shape, wherein the detected shape is a rectangle, wherein the portion of the text that is detected comprises an equation and variables, then the variables on a left side of the equation are considered as an output port. In further exemplary methods, if portions of the text that is detected comprise equations and variables, wherein the variables and text of the equations are considered as input ports or output ports, wherein a table of input ports and a table of output ports are created, and wherein if a variable is found in both an input ports table and an output ports table then the variable is deleted from an input ports table and an output ports table. In additional exemplary methods, if portions of the text that is detected comprise equations and variables, wherein the variables and text of the equations are assigned as input ports or output ports, wherein a table of input ports and a table of output ports are created, and wherein a variable is found in both an input ports table and an output ports table, then the variable is assigned as logic. In further exemplary methods, linting is not done and the register transfer level hardware description language code is a synthesizable register transfer level hardware description language code.

Exemplary devices for converting a flow chart are provided. Exemplary devices include least one machine-readable storage medium comprising non-transitory instructions, that when executed by a processor, cause a device to select an architectural specification for at least a portion of a semiconductor chip wherein the architectural specification is in a form of a structured flow chart, detect shapes in the structured flow chart and generate a first array of values wherein the first array of values comprises a value for each shape detected and the values of the first array of values are ordered according to locations of the shapes detected, detect lines in the structured flow chart and generate a second array of values wherein the second array of values comprises a value for each line detected and the values of the second array of values are ordered according to locations of the lines detected, detect text in the structured flow chart and generate a third array of values wherein the third array of values comprises a value for each block of text detected and values of the third array are ordered by location of the text detected, and convert information contained in the first array of values, second array of values, and third array of values into a register transfer level hardware description language code. A hardware description language is, for example, system Verilog, very high speed integrated circuits hardware description language, or Verilog. Exemplary non-transitory instructions, that when executed by a processor, can also cause a device to create a copy of the structured flow chart wherein the copy is in red green blue (RGB) pixel format. The shapes detected are, for example, rounded, rhombus, and rectangle. A rounded shape can represent state, a rhombus can represent a decision, and a rectangle can represent an assignment for a finite state machine. In further examples, if a portion of the text that is detected is associated with a detected shape, and the detected shape is a rhombus, and the portion of the text that is detected comprises an equation and variables, then the variables on a left side of the equation are considered as an input port. In additional examples, if a portion of the text that is detected is associated with a detected shape, the detected shape is a rhombus, and the portion of the text that is detected comprises an equation and variables, then the variables on a right side of the equation are considered as an output port. In additional examples, if a portion of the text that is detected is associated with a detected shape, wherein the detected shape is a rectangle, and wherein the portion of the text that is detected comprises an equation and variables, then the variables on a right side of the equation are considered as an input port. In additional examples if a portion of the text that is detected is associated with a detected shape, wherein the detected shape is a rectangle, and wherein the portion of the text that is detected comprises an equation and variables, then the variables on a left side of the equation are considered as an output port. In further examples, if portions of the text that is detected comprise equations and variables, wherein the variables and text of the equations are considered as input ports or output ports, wherein a table of input ports and a table of output ports are created, and wherein a variable is found in both an input ports table and an output ports table, then the variable is deleted from an input ports table and an output ports table. In additional examples, if portions of the text that is detected comprise equations and variables, wherein the variables and text of the equations are assigned as input port or an output port, wherein a table of input ports and a table of output ports are created, and wherein a variable is found in both an input ports table and an output ports table, then the variables is assigned as logic. In further examples linting is not done and the register transfer level hardware description language code is a synthesizable register transfer level hardware description language code.

In addition to what is described herein, various modifications can be made to what is disclosed and implementations of the invention without departing from their scope. Therefore, the illustrations and examples herein should be construed in an illustrative, and not a restrictive sense.

What is claimed is:

1. A method for converting a flow chart comprising:
selecting a microarchitectural specification for at least a portion of a semiconductor chip wherein the microarchitectural specification is in a form of a structured flow chart;
detecting shapes in the structured flow chart and generating a first array of values wherein the first array of values comprises a value for each shape detected and the values of the first array of values are ordered according to locations of the shapes detected;
detecting lines in the structured flow chart and generating a second array of values wherein the second array of values comprises a value for each line detected and the values of the second array of values are ordered according to locations of the lines detected;
detecting text in the structured flow chart and generating a third array of values wherein the third array of values comprises a value for each block of text detected and values of the third array are ordered by location of the text detected; and
converting information contained in the first array of values, the second array of values, and the third array of values into a register transfer level hardware description language code.

2. The method of claim 1 wherein a hardware description language is system Verilog, very high speed integrated circuits hardware description language, or Verilog.

3. The method of claim 1 also including creating a copy of the structured flow chart wherein the copy is in red green blue (RGB) pixel format.

4. The method of claim 1 wherein a portion of the text that is detected is associated with a detected shape, wherein the detected shape is a rhombus, wherein the portion of the text that is detected comprises an equation and variables, and wherein the variables on a left side of the equation are considered as an input port.

5. The method of claim 1 wherein a portion of the text that is detected is associated with a detected shape, wherein the detected shape is a rhombus, wherein the portion of the text that is detected comprises an equation and variables, and wherein the variables on a right side of the equation are considered as an output port.

6. The method of claim 1 wherein a portion of the text that is detected is associated with a detected shape, wherein the detected shape is a rectangle, wherein the portion of the text that is detected comprises an equation and variables, and wherein the variables on a right side of the equation are considered as an input port.

7. The method of claim 1 wherein a portion of the text that is detected is associated with a detected shape, wherein the detected shape is a rectangle, wherein the portion of the text that is detected comprises an equation and variables, and wherein the variables on a left side of the equation are considered as an output port.

8. The method of claim 1 wherein portions of the text that is detected comprise equations and variables, wherein the variables and text of the equations are considered as input ports or output ports, wherein a table of input ports and a table of output ports are created, wherein a variable is found in both an input ports table and an output ports table, and wherein the variable is deleted from the input ports table and the output ports table.

9. The method of claim 1 wherein portions of the text that is detected comprise equations and variables, wherein the variables and text of the equations are assigned as input ports or output ports, wherein a table of input ports and a table of output ports are created, and wherein if a variable is found in both an input ports table and an output ports table the variable is assigned as logic.

10. The method of claim 1 wherein linting is not done and the register transfer level hardware description language code is a synthesizable register transfer level hardware description language code.

11. At least one machine-readable storage medium comprising non-transitory instructions, that when executed by a processor, cause a device to:
select an architectural specification for at least a portion of a semiconductor chip wherein the architectural specification is in a form of a structured flow chart;
detect shapes in the structured flow chart and generate a first array of values wherein the first array of values comprises a value for each shape detected and the values of the first array of values are ordered according to locations of the shapes detected;
detect lines in the structured flow chart and generate a second array of values wherein the second array of values comprises a value for each line detected and the values of the second array of values are ordered according to locations of the lines detected;
detect text in the structured flow chart and generate a third array of values wherein the third array of values comprises a value for each block of text detected and values of the third array are ordered by location of the text detected; and
convert information contained in the first array of values, second array of values, and third array of values into a register transfer level hardware description language code.

12. The at least one machine-readable storage medium of claim 11 wherein a hardware description language is system Verilog, very high speed integrated circuits hardware description language, or Verilog.

13. The at least one machine-readable storage medium of claim 11 wherein the shapes detected are rounded, rhombus, and rectangle and wherein a rounded shape represents state, a rhombus represents a decision, and a rectangle represents an assignment for a finite state machine.

14. The at least one machine-readable storage medium of claim 11 wherein a portion of the text that is detected is associated with a detected shape, wherein the detected shape is a rhombus, wherein the portion of the text that is detected comprises an equation and variables, and wherein the variables on a left side of the equation are considered as an input port.

15. The at least one machine-readable storage medium of claim 11 wherein a portion of the text that is detected is associated with a detected shape, wherein the detected shape is a rhombus, wherein the portion of the text that is detected comprises an equation and variables, and wherein the variables on a right side of the equation are considered as an output port.

16. The at least one machine-readable storage medium of claim 11 wherein a portion of the text that is detected is associated with a detected shape, wherein the detected shape is a rectangle, wherein the portion of the text that is detected comprises an equation and variables, and wherein the variables on a right side of the equation are considered as an input port.

17. The at least one machine-readable storage medium of claim 11 wherein a portion of the text that is detected is associated with a detected shape, wherein the detected shape is a rectangle, wherein the portion of the text that is detected comprises an equation and variables, and wherein the variables on a left side of the equation are considered as an output port.

18. The at least one machine-readable storage medium of claim 11 wherein portions of the text that is detected comprise equations and variables, wherein the variables and text of the equations are considered as input ports or output ports, wherein a table of input ports and a table of output ports are created, and wherein if a variable is found in both an input ports table and an output ports table the variable is deleted from the input ports table and the output ports table.

19. The at least one machine-readable storage medium of claim 11 wherein portions of the text that is detected comprise equations and variables, wherein the variables and text of the equations are assigned as input ports or output ports, wherein a table of input ports and a table of output ports are created, and wherein if a variable is found in both a input ports table and a output ports table the variable is assigned as logic.

20. The at least one machine-readable storage medium of claim 11 also including creating a copy of the structured flow chart wherein the copy is in red green blue (RGB) pixel format.
